(19) United States
(12) Patent Application Publication
(10) Pub. No.: US 2017/0029968 A1
(43) Pub. Date: Feb. 2, 2017

(54) HIERARCHICAL CELLULAR MATERIALS AND METHOD OF MAKING AND USING THE SAME

(71) Applicant: University of Virginia Patent Foundation, Charlottesville, VA (US)

(72) Inventors: Haydn N.G. WADLEY, Keswick, VA (US); Vikram DESHPANDE, Cambridge (GB)

(21) Appl. No.: 15/303,916

(22) PCT Filed: Apr. 14, 2015
(86) PCT No.: PCT/US15/25736

§ 371 Date: Oct. 13, 2016

Related U.S. Application Data
(60) Provisional application No. 61/979,264, filed on Apr. 14, 2014.

(51) Int. Cl. C25D 1/00; C23C 14/00; G03F 7/00; C23C 14/34; C25D 1/08; C25D 1/20

(52) U.S. Cl. CPC C25D 1/006; C25D 1/08; C25D 1/20; G03F 7/0015; C23C 14/34; C23C 14/0005

(57) ABSTRACT

Cellular materials and methods of making and using the cellular materials.

### RELATED APPLICATIONS

This application claims priority from U.S. Provisional Application No. 61/979,264 filed Apr. 14, 2014, under 35 U.S.C. §119 (e) and PCT Article 8.

### FIELD

This application is directed to hierarchical cellular materials or composites, and methods of making and using these hierarchical cellular material or composites.

### BACKGROUND

There exists an ongoing need to further develop new materials for various engineering applications. The development of new materials, in particular hierarchical cellular materials appears promising.

### SUMMARY

A method of making a cellular material.

A method of making an improved cellular material.

A method of making a cellular material comprising or consisting of conducting phase separation of block copolymers resulting in a particular morphology; selective removal of one polymer from the block copolymers to form a lattice; conducting metal deposition on the lattice; and dissolving a remaining polymer to obtain the cellular material.

A method of making a gyroid, in particular a metal gyroid.

A method of making a double gyroid, in particular a double metal gyroid.

A method of making an octet truss.

A method of making a metal cellular material comprising conducting metal deposition on cellular material.

A method of making metal cellular material comprising or consisting of conducting metal deposition on a cellular material by electrodeposition.

A method of making a cellular material using block copolymer poly(4-fluorostyrene-r-styrene)-b-poly(d,l-lactide) (PFS-b-PLA).

A method of making a metal gyroid having a strut diameter of 13 nm.

A method of making a metal gyroid having a unit-cell size of 45 nm.

A method of making a metal gyroid having a grain size of 500 nm to 1 micron.

A method of making a metal gyroid having a volume fraction of 40%.

A method of making an octet lattice from a gyroid nanolattice.

A method of making an octet lattice from an octet nanolattice.

A method of making trusses comprising or consisting of laser cutting the cellular material to make the trusses.

A method of making an octet lattice comprising or consisting of laser cutting the cellular material to make octet lattice.

A method of making octet lattice comprising or consisting of laser cutting the cellular material to make octet lattice.

A method of making a hierarchical octet lattice comprising or consisting of assembling the trusses and octet lattice to form the hierarchical octet lattice.

A method of making a nanolattice comprising or consisting of generating a CAD design for the nanolattice; using two-photon lithography to generate a polymer skeleton; conducting sputter/ALD deposition on the polymer skeleton; exposing internal polymer of polymer skeleton; and plasma etching polymer skeleton to form a hollow nanolattice.

Certain cellular materials made to this point are bounded by those that are 1) strong but not fracture resistant, or 2) not strong (i.e., weaker), yet more fracture resistant (i.e., tougher).

One aspect identifies a new state of matter that results in a material that is very strong, has high toughness with a density less than that of water. A further aspect is based upon the fabrication of lattice cellular structures with strut diameters in the millimeter range made from nanofoams whose ligaments widths are in the 10 nm to 10 micrometer range.

A further aspect is directed to materials, and methods of making and using the same, based on nanoscale structures that are arranged in a hierarchical levels of structural elements from nano to large scale. These materials provide for desirable properties such as an unusual combination of strength and toughness.

Properties of interest that these materials can provide include, but are not limited to, high fracture toughness (e.g., 1-100 s MPa·m1/2), strength, low density (e.g., 1-100 s kg/m3), high compressive strength (e.g., 1-1000 MPa), high Young's Modulus (GPa).

Materials of interest for use in preparation of the subject materials include, but are not limited to, styrene template materials, e.g., polystyrene-b-polyisoprene (PS-b-PI), poly(4-fluorostyrene-r-styrene)-b-poly(d,l-lactide) (PFS-b-PLA). Materials which the structural elements of the subject materials may be composed include, but are not limited to, metals, metal containing substances, Ni, NiAl3, NiAL-1.0Ta, NiAl-0.2Hf, SiC, carbon, etc.

Structures of interest for use in constructing the subject materials include, but are not limited to, gyroid nanolattices, octet nanolattices, cellular structures, nanofoams, nanoscale ligaments, double gyroid structures, lamellae, cylinder, sphere, octet truss, honeycomb, or any structures.

In some cases, the nanostructures have features on a low nm scale, e.g., 10 nm diameter scale.

Methods of preparation of gyroid materials (for example, see figure directed toward double-gyroid) include use of polystytrene templates where polystyrene polymers may be selectively removed (e.g., by phase separation of block copolymers, dissolution, laser cutting) to create a template to which the material of interest may be added.

It should be appreciated that various sizes, dimensions, contours, rigidity, shapes, flexibility and materials of any of the components or portions of components in the various embodiments discussed throughout may be varied and utilized as desired or required.

It should be appreciated that while some dimensions may or may not be provided on the aforementioned figures, the device may constitute various sizes, dimensions, contours, rigidity, shapes, flexibility and materials as it pertains to the components or portions of components of the device, and therefore may be varied and utilized as desired or required.

It should be appreciated that any of the components or modules referred to with regards to any of the present invention embodiments discussed herein, may be integrally or separately formed with one another. Further, redundant functions or structures of the components or modules may be implemented.

It should be appreciated that the device and related components discussed herein may take on all shapes along the entire continual geometric spectrum of manipulation of x, y and z planes to provide and meet the structural demands and operational requirements. Moreover, locations and alignments of the various components may vary as desired or required.

Practice of an aspect of an embodiment (or embodiments) of the invention will be still more fully understood from the following examples and results, which are presented herein for illustration only and should not be construed as limiting the invention in any way.

The various embodiments of the structures, compositions, systems, devices, and materials discussed in the main body of this disclosure may be utilized and implemented for a number of products and services. For instance, it should be appreciated the following provides a non-limiting list of examples that represent embodiments that are considered part of the present invention and may, of course, be employed within the context of the invention.
1. Heat Pipe System, structures, or devices,
2. Heat Sink system, structures, or devices,
3. Thermal Management Systems (TMS),
4. Ballistic resistant and mitigation devices, structures, and systems,
5. Projectile resistant and mitigation devices, structures, and systems,
6. Missile resistant and mitigation devices, structures, and systems,
7. Blast resistant and mitigation devices, structures, and systems,
8. Heat resistant devices, structures, and systems,
9. Electrical insulating devices, structures, and systems,
10. Armor plating system, device, or structure,
11. Tank plating system, device, or structure,
12. Armor system, device, or structure,
13. Lattice structure (for example, but not limited thereto, tetrahedral, pyramidal, three-dimension kagome, kagome, or any combination thereof),
14. Cellular structure,
15. Corrugation structure (for example, but not limited thereto, triangular, diamond, multi-layered, flat-top, Navtruss, or any combination thereof),
16. Honeycomb structure (for example, but not limited thereto, hexagonal cell, square cell, cylindrical, rectangular cell, triangular cell or any combination thereof),
17. Panel structure,
18. Face layer,
19. Sandwich structure,
20. Modular layer structure or multilayer component,
21. Multifunctional structure or component,
22. Smart memory alloy (SMA) system, device, or structure,
23. Textile weave structure, woven structure, mesh structure, braid structure, multilayer textile structure, or any combination thereof,
24. Architectural structure (for example: pillars, walls, shielding, foundations or floors for tall buildings or pillars, wall shielding floors, for regular buildings and houses),
25. Civil engineering field structure (for example: road facilities such as noise resistant walls and crash barriers, road paving materials, permanent and portable aircraft landing runways, permanent or portable landing pads, pipes, segment materials for tunnels, segment materials for underwater tunnels, tube structural materials, main beams of bridges, bridge floors, girders, cross beams of bridges, girder walls, piers, bridge substructures, towers, dikes and dams, guide ways, railroads, ocean structures such as breakwaters and wharf protection for harbor facilities, floating piers/oil excavation or production platforms, airport structures such as runways), military security/protection/defense structures;
26. Machine structure (for example: frame structures for carrying system, carrying pallets, frame structure for robots, etc.),
27. Automobile structure (for example: body, frame, doors, chassis, roof and floor, side beams, bumpers, etc.),
28. Ship structure (for example: main frame of the ship, body, deck, partition wall, wall, etc.),
29. Freight car structure (for example: body, frame, floor, wall, etc.),
30. Aircraft structure (for example: wing, main frame, body, floor, etc.),
31. Spacecraft structure (for example: body, frame, floor, wall, etc.),
32. Space station structure (for example: the main body, floor, wall, etc.), and
33. Submarine, ship or water craft structure (for example: body, frame, etc.).
34. Military vehicle (tank, automobile, robot, etc.),
35. Parts for marine vessel hulls or decks or parts for hovercraft, and other amphibious vehicles,
36. Frames to any air, space, or water craft, vehicle or robot,
37. Outer skin or inner skin, as well as other components, of any air, space, or water craft, vehicle or robot,
38. Any building structures or components of building structures,
39. Any automotive component, bodies, frames, chassis and components,
40. Transportation land, air, or sea vehicle, craft or robot,
41. Electronics systems or components of such electronic systems, as well as other components and housings,
42. Multifunctional system, device, or structure,
43. Struts or the like,
44. Jet Blast Deflector (JBD) system,
45. Armor suit (or portions thereof) for military personnel or other human or animal subjects,
46. Armor shield for military personnel or other human or animal subjects,
47. Armor helmet or mask (or portions thereof) for military personnel or other human or animal subjects,
48. Armor gear (or portions thereof) and accessories for military personnel or other human or animal subjects,
49. Armor suit for military robot or other types of robots,
50. Rods, bars or other elongated members,
51. I-beam, H-beam, or other beam like structures,
52. Impact resistant and mitigation devices, structures, and systems,
53. Force resistant and mitigation devices, structures, and systems,
54. Shock absorption devices, structures, and systems,
55. Crash deflection and mitigation devices, structures, and systems,

### BRIEF DESCRIPTION OF DRAWINGS

FIG. 1 is a screen shot of Hybrid Cellular Materials.

FIG. 2 is a screen shot showing an “Ashby” map.

FIG. 3 is a screen shot showing a map of compressive strength verses density for engineering materials.

FIG. 4 is a screen shot showing a map of fracture toughness verses density of engineering materials.

FIG. 5 is a screen shot showing a map of fracture toughness verses strength of engineering materials.

FIG. 6 is a screen shot showing examples of various types of cellular structures.

FIG. 7 is a screen shot showing a map of elastic modulus (Young's modulus) verses density map.

FIG. 8 is a screen shot showing a graph of average engineering stress at 1% strain verses specimen diameter.

FIG. 9 is a screen shot showing a diagram of increasing molecular weight verses increasing volume fraction of red component.

FIG. 10 is a screen shot showing the manufacture of a metal gyroid (e.g. “double-gyroid”).

FIG. 11 is a screen shot showing the parent material properties from various measurements.

FIG. 12 is a screen shot showing other options for nano-scale lattice manufacture.

FIG. 13 is a screen shot showing a whole range of topologies manufactured by this process.

FIG. 14 is a screen shot showing a map of compressive strength verses density for various lattices achieved to date.

FIG. 15 is a screen shot showing a map of compressive strength verses density for carbon based systems.

FIG. 16 is a screen shot showing that millimeter scale lattices tend to be intrinsically tough.

FIG. 17 is a screen shot showing a graph of force verses crack-mouth opening displacement and test sample.

FIG. 18 is a screen shot showing a graph of dimensionless toughness verse relative density.

FIG. 19 is a screen shot showing micro-architectured materials, including gyroid and octet truss.

FIG. 20 is a screen shot showing a graph of fracture toughness verses strength.

FIG. 21 is a screen shot showing the structures of octet lattice from gyroid nanolattice and octet lattice fro octet nanolattice.

FIG. 22 is a screen shot showing the detail structure of octet lattice from octet nanolattice.

FIG. 23 is a screen shot showing a graph of fracture toughness verses strength for various hierarchical materials.

FIG. 24 is a screen shot of making hybrid gyroid lattices.

FIG. 25 is a screen shot showing the making of gyroid material.

FIG. 26 is a screen shot showing making hierarchical octet lattice assembly.

FIG. 27 is a screen shot showing making gyroid material.

FIG. 28 is a screen shot showing making a hierarchical octet lattice assembly.

FIG. 29 is a screen shot showing making gyroid material octet lattice via ALD.

### DETAILED DESCRIPTION

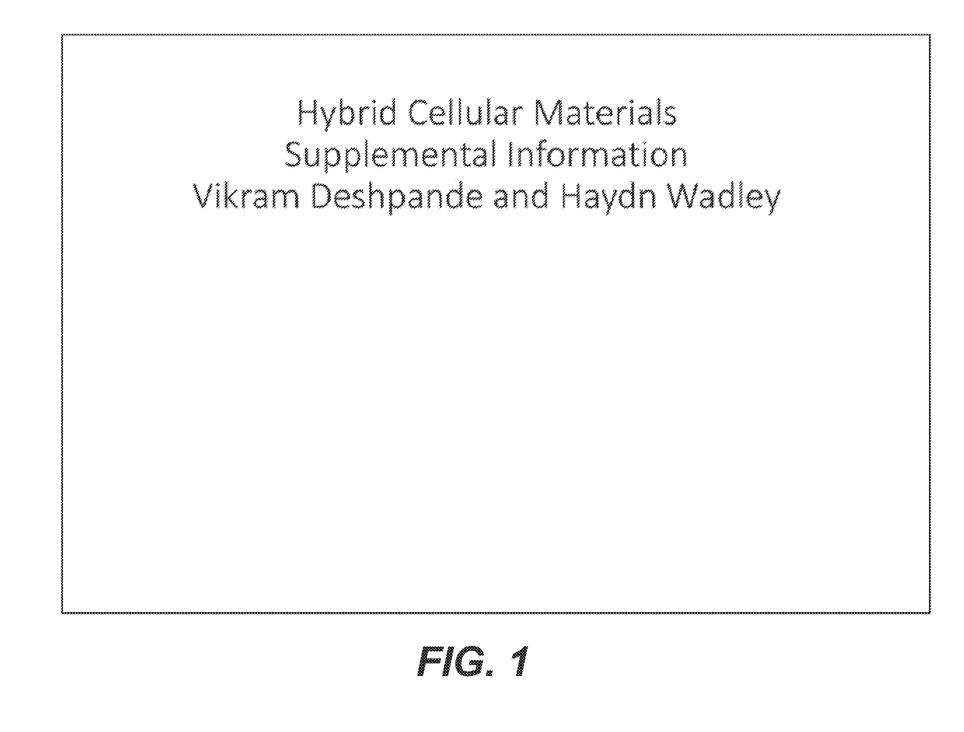

A Hybrid Cellular Materials is shown in FIG. 1.

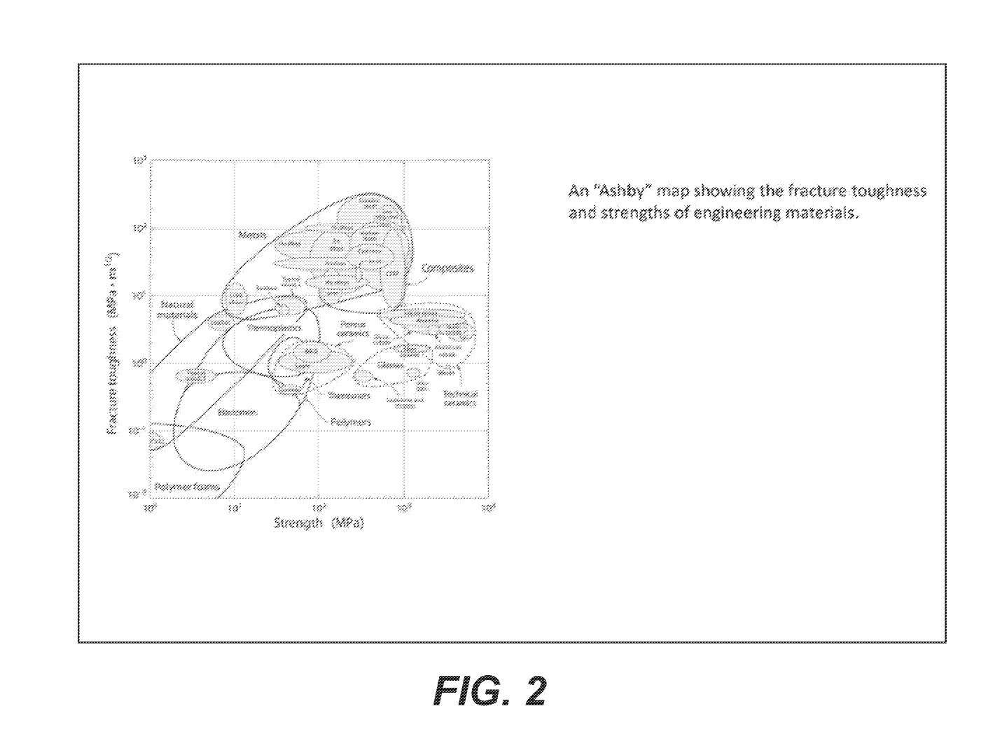

An “Ashby” map showing the fracture toughness and strengths of engineering materials is shown in FIG. 2.

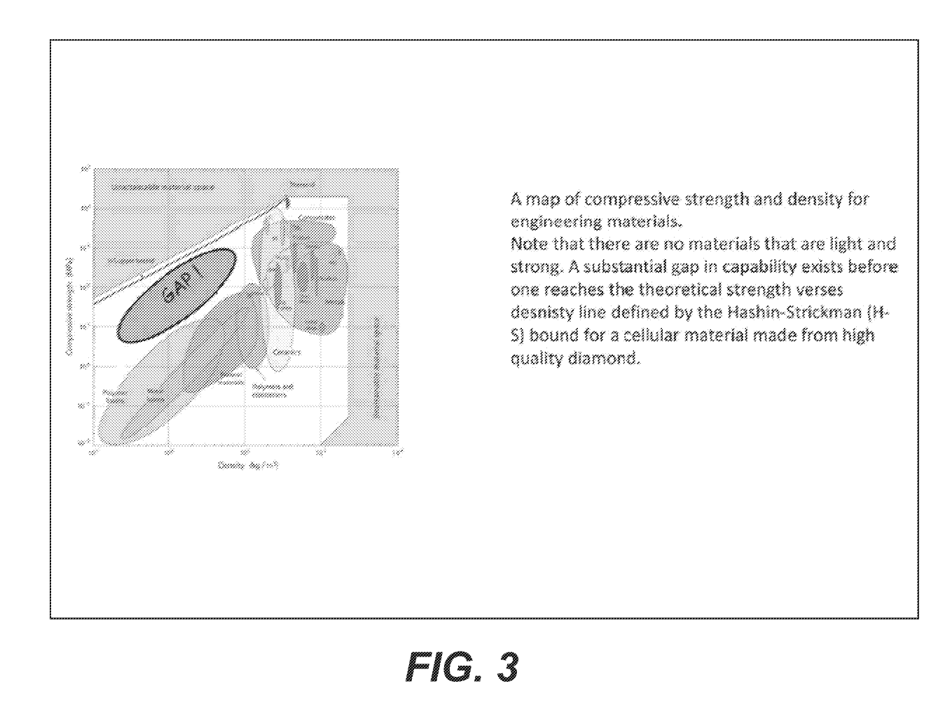

A map of compressive strength and density for engineering materials is shown in FIG. 3. Note that there are no materials that are light and strong. A substantial gap in capability exists before one reaches the theoretical strength verses density line defined b the Hashin-Strickman (H-S) bound for a cellular material made from high quality diamond.

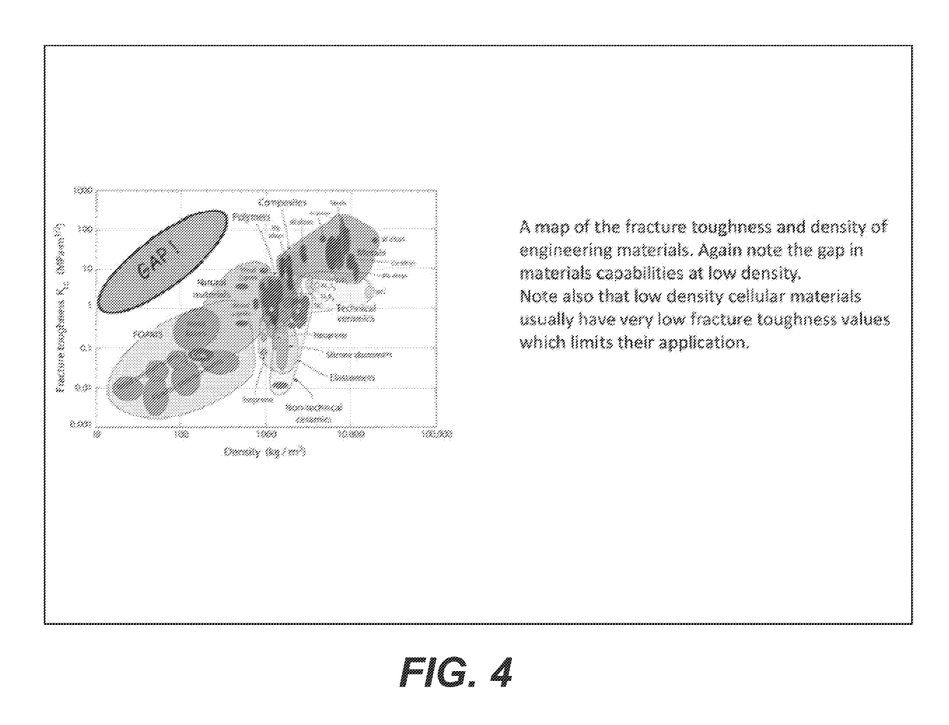

A map of the fracture toughness and density of engineering materials in shown in FIG. 4. Again note the gap in materials capabilities at low density. Note also that low density cellular materials usually have very low fracture toughness values which limits their applications.

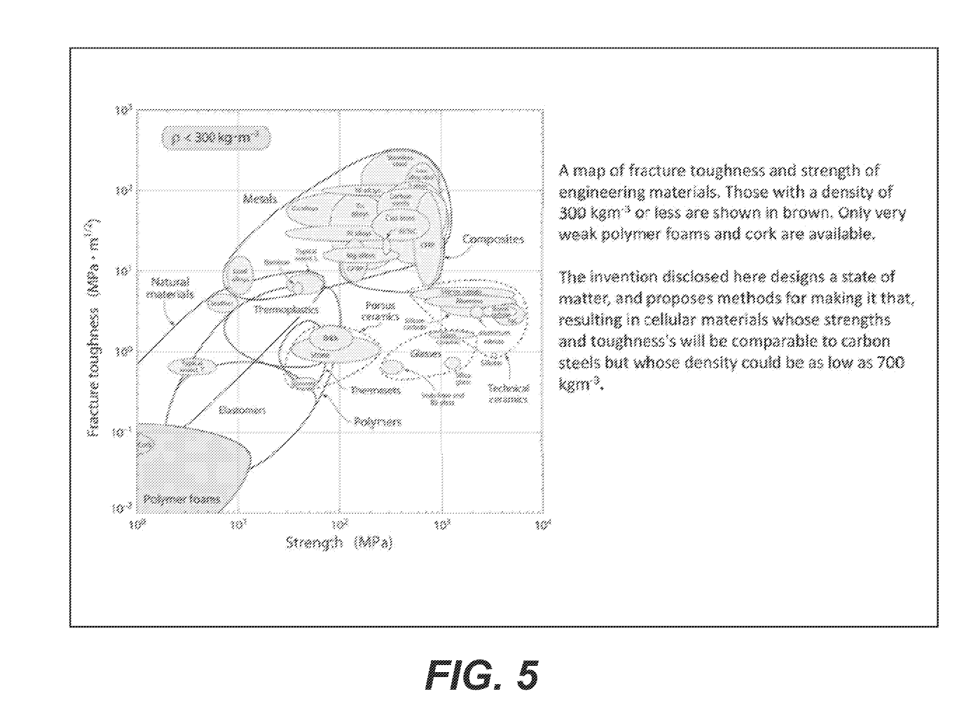

A map of fracture toughness and strength of engineering materials is shown in FIG. 5. Those with a density of 300 kgm³ or less are shown dark shaded. Only very weak polymer foams and cork are available. The invention disclosed here designs a state of matter, and proposes methods for making it that, resulting in cellular materials whose strengths and toughness's will be comparable to carbon steels but whose density could be as low as 700 kgm³.

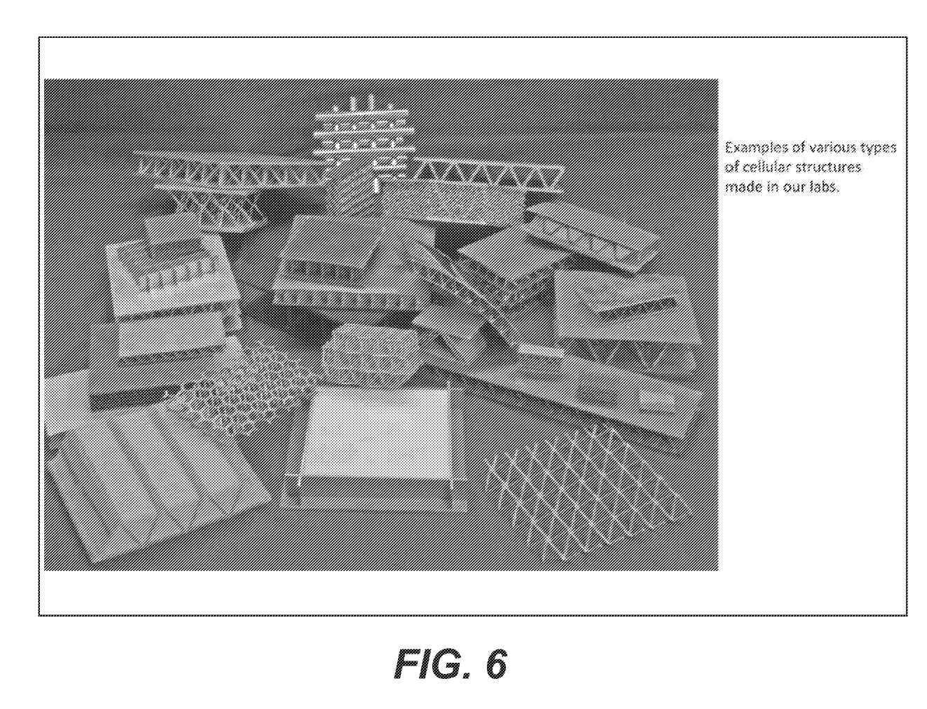

Examples of various types of cellular structures is shown in FIG. 6.

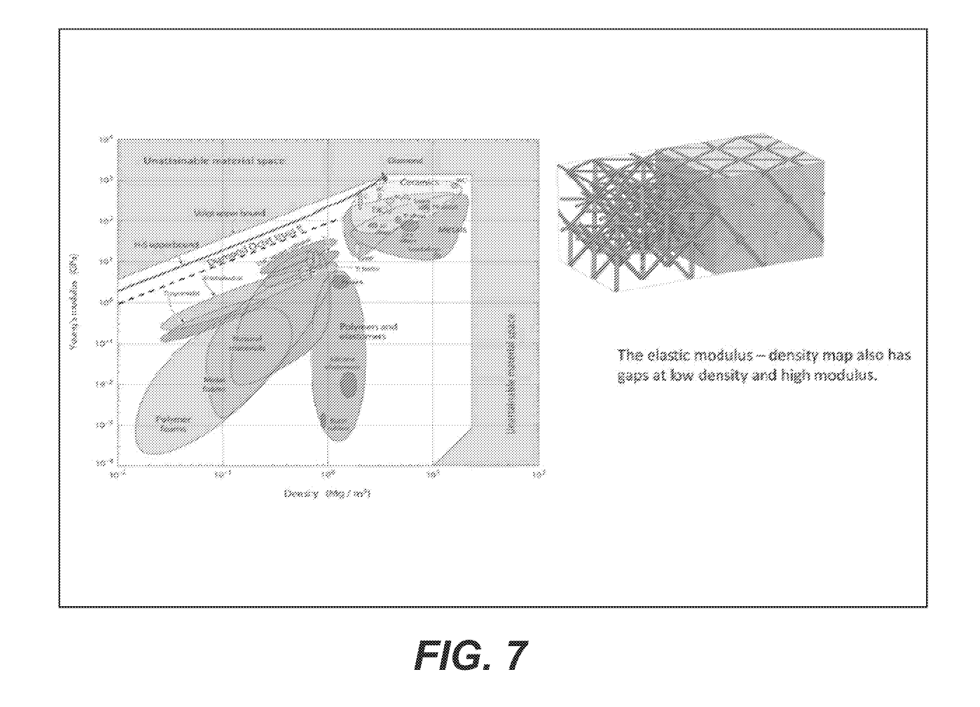

An elastic modulus-density map is shown in FIG. 7. The elastic modulus-density map also has gaps at low density and high modulus.

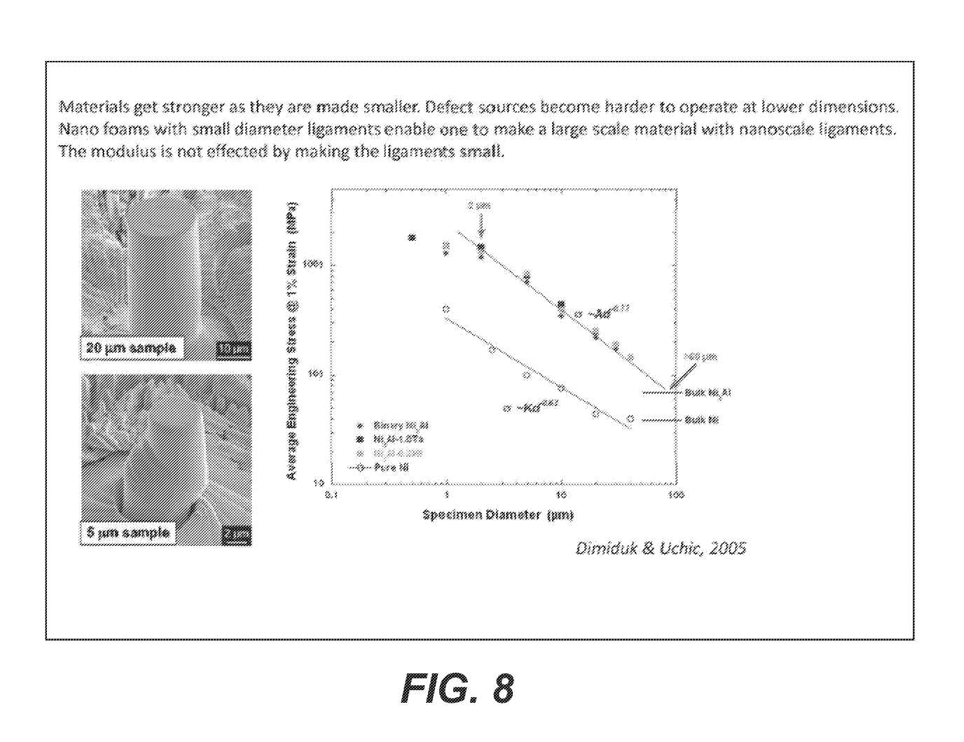

An average engineering stress at 1% strain verses specimen diameter is shown in FIG. 8. Materials get stronger as they are made smaller. Defect sources become harder to operate at lower dimensions. Nano foams with small diameter ligaments enable one to make a large scale material with nanoscale ligaments. The modulus is not effected by making the ligaments small.

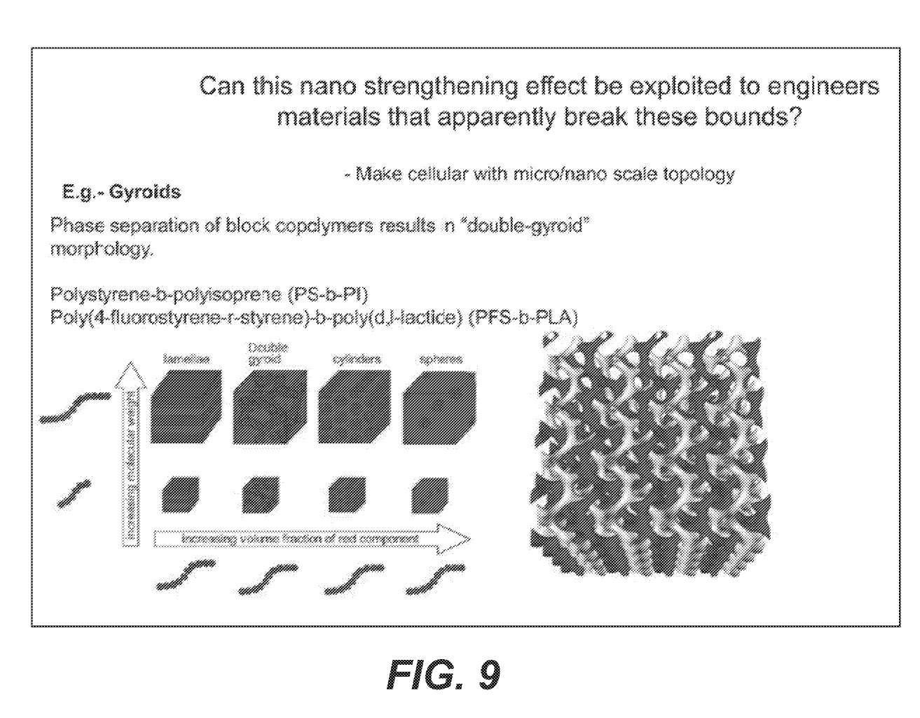

A diagram of increasing molecular weight verses increasing volume fraction of red component is shown in FIG. 9. For example, polystyrene-b-polyisoprene (PS-b-PI) and poly(4-fluorostyrene-r-styrene)-b-poly(d,l-lactide) (PFS-b-PLA). Phase separation of block copolymers results in a “double-gyroid” morphology as shown.

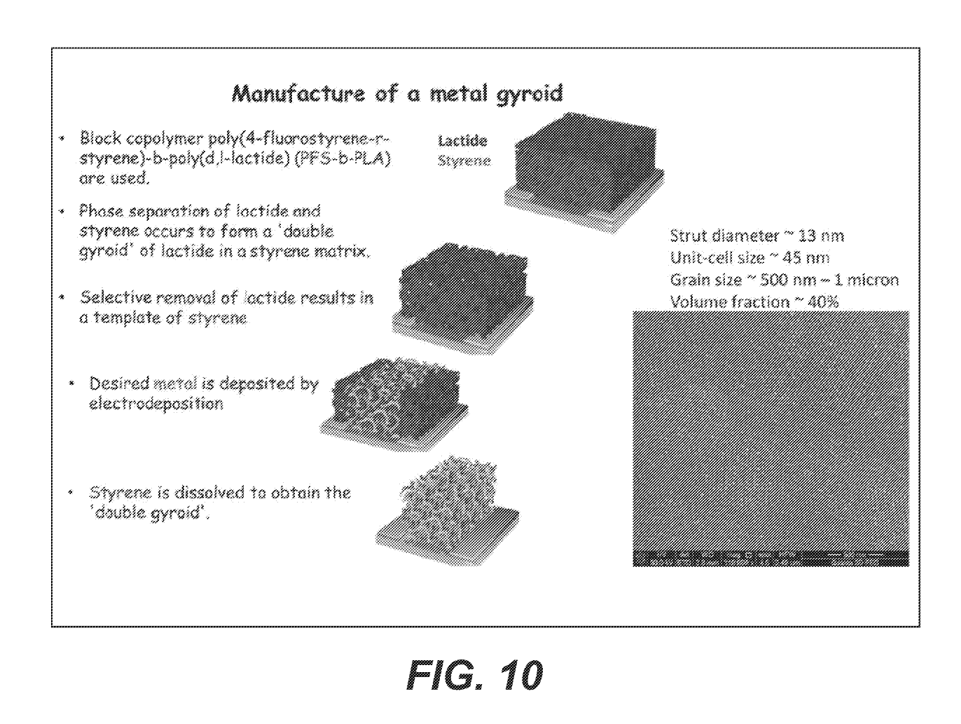

The manufacture of a metal gyroid is illustrated in FIG. 10. A block copolymer poly(4-fluorostyrene-r-styrene)-b-poly(d,l-lactide) (PFS-b-PLA) is used. A phase separation of lactide and styrene occurs to form a “double gyroid” of lactide in a styrene matrix. The selective removal of lactide results in a template of styrene. A desired metal is deposited by electrodeposition. The styrene is dissolved to obtain the “double gyroid.” For example, this results in a material with a strut diameter of approx. 13 nm; a unit-cell size of approx. 45 nm; a grain size of approx. 500 nm-1 micron; and a volume fraction of approx. 40%.

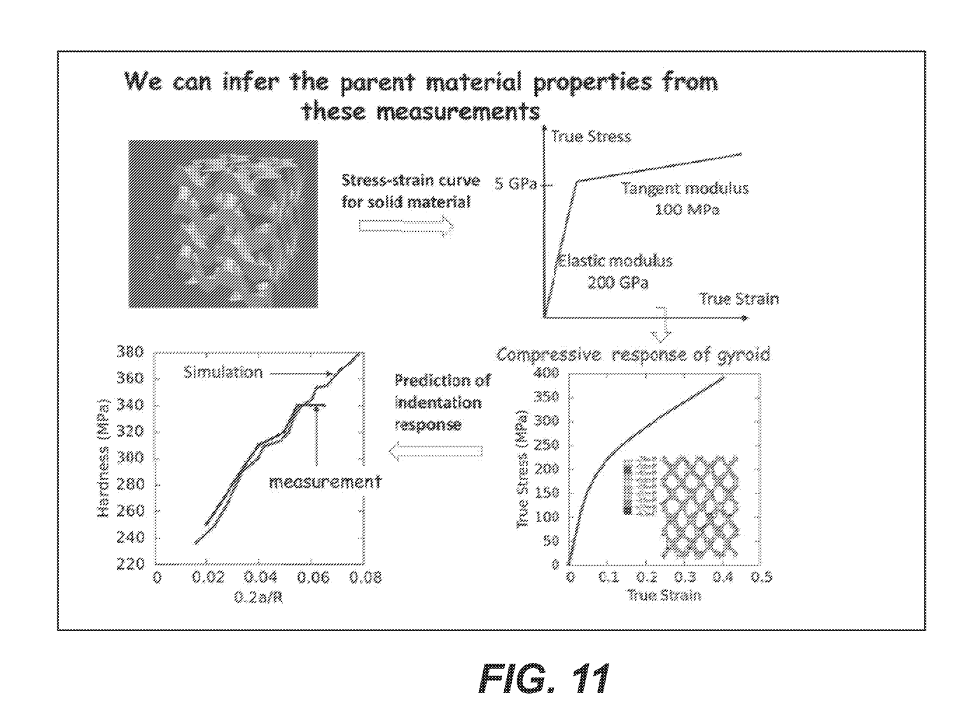

The parent material properties can be inferred from various measurements illustrated in FIG. 11. For example, comparing a stress verses strain curve for a solid material and a stress verses strain for a gyroid. Further, a hardness verses 0.2 a/R is simulated and measured and compared.

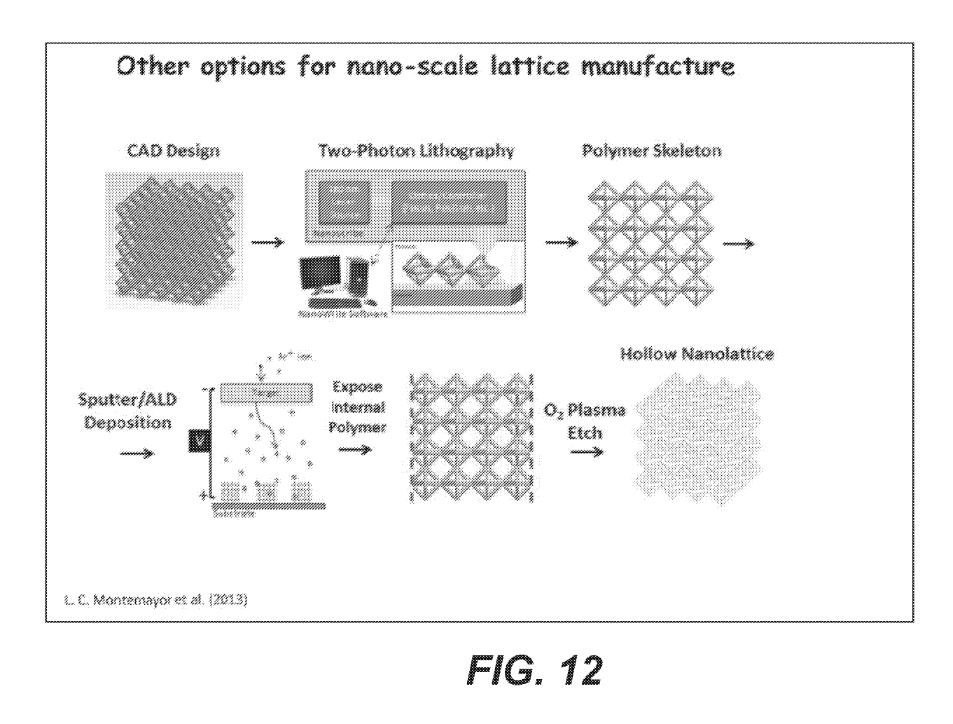

Other options for nano-scale lattice manufacture is shown in FIG. 12. For example, a CAD design is developed; two-photon lithography is used to generate a polymer skeleton; sputter/ALD deposition is used to generate an expose internal polymer; and O₂ plasma etch is used to generate a hollow nanolattice.

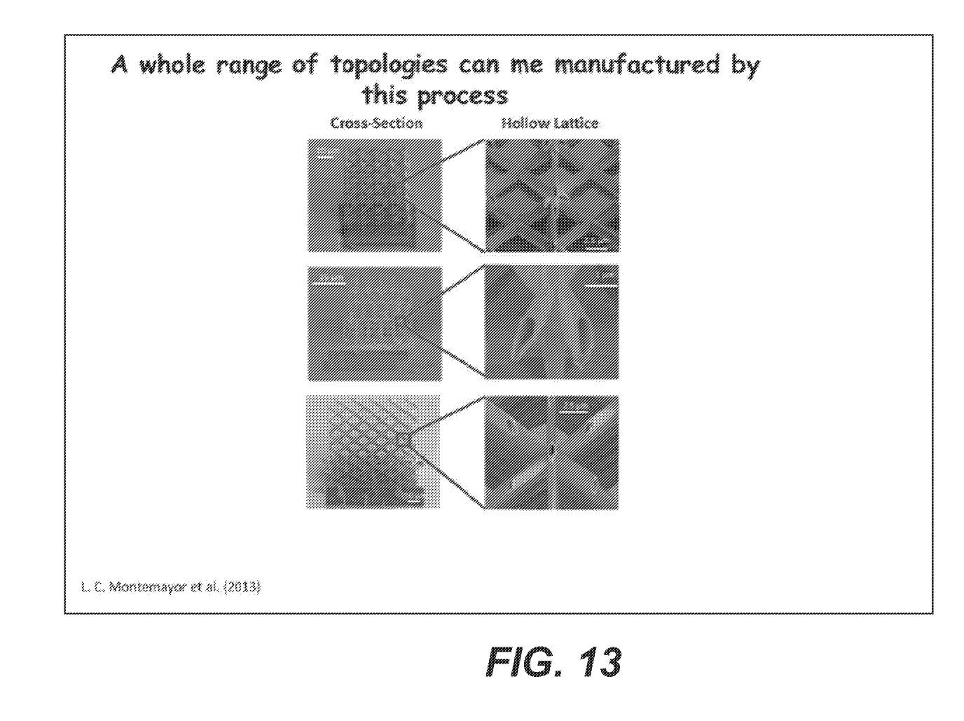

A whole range of topologies can be manufactured by this process, as shown in FIG. 13.

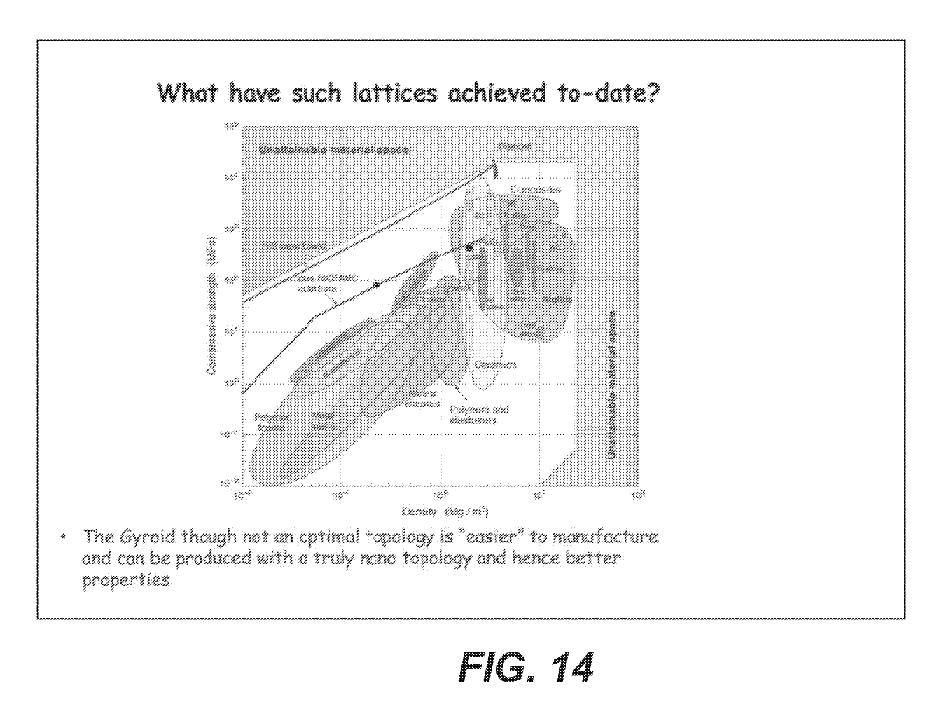

A graph of compressive strength verses density for lattices achieved to date is shown in FIG. 14. The gyroid though not an optimal topology is “easier” to manufacture and can be produced with a truly nano topology and hence better properties.

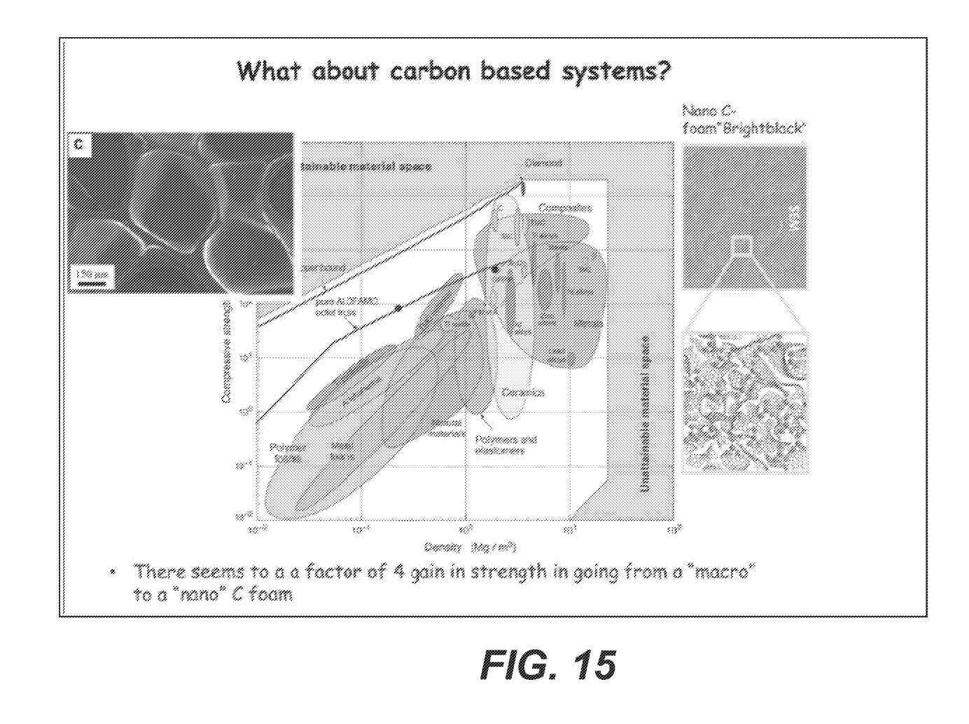

A graph of compressive strength verses density for carbon based systems is shown in FIG. 15. There seems to be a factor of 4 gain in strength in going from a “macro” to a “nano” C foam.

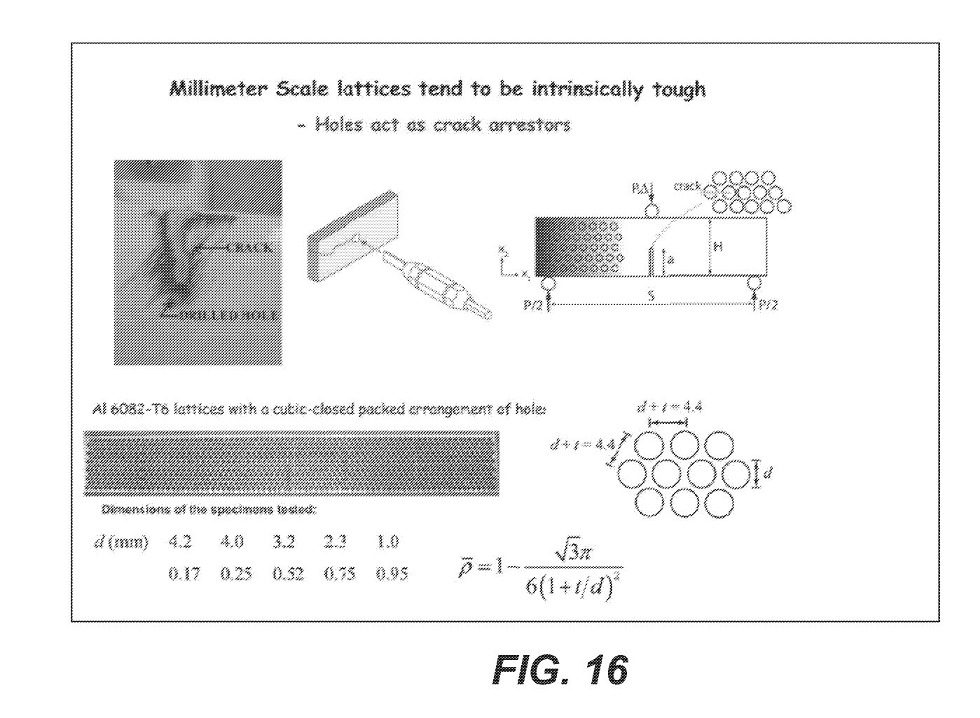

Millimeter scale lattices tend to be intrinsically tough, as shown in FIG. 16. Holes act as crack arrestors.

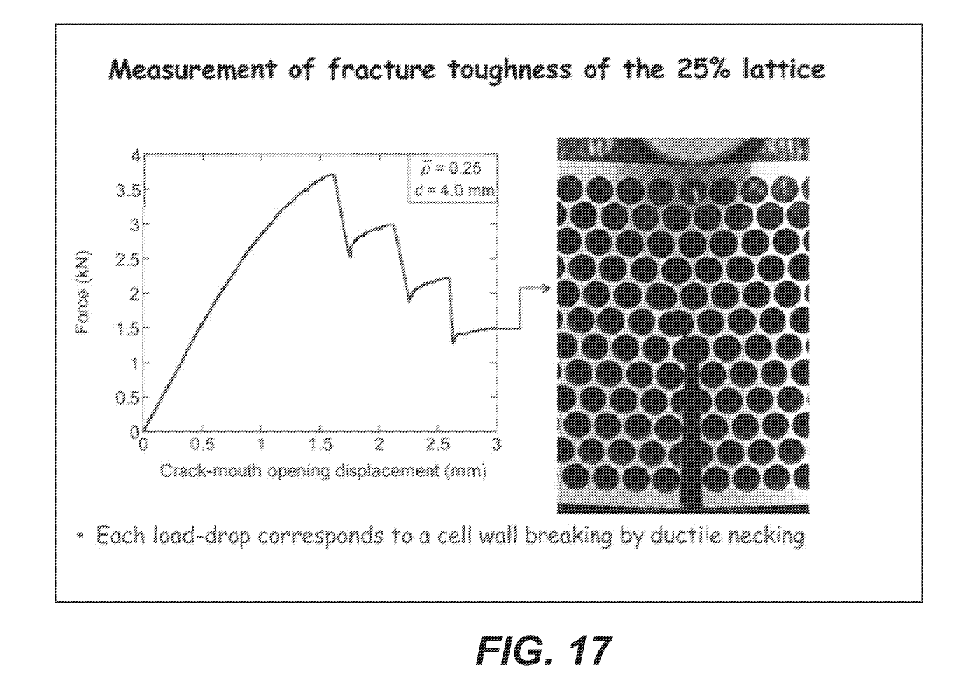

A measurement of fracture toughness of a 25% lattice is shown in FIG. 17. A graph of force verses crack-mouth opening displacement and test sample is shown. Each load-drop corresponds to a cell wall breaking by ductile necking.

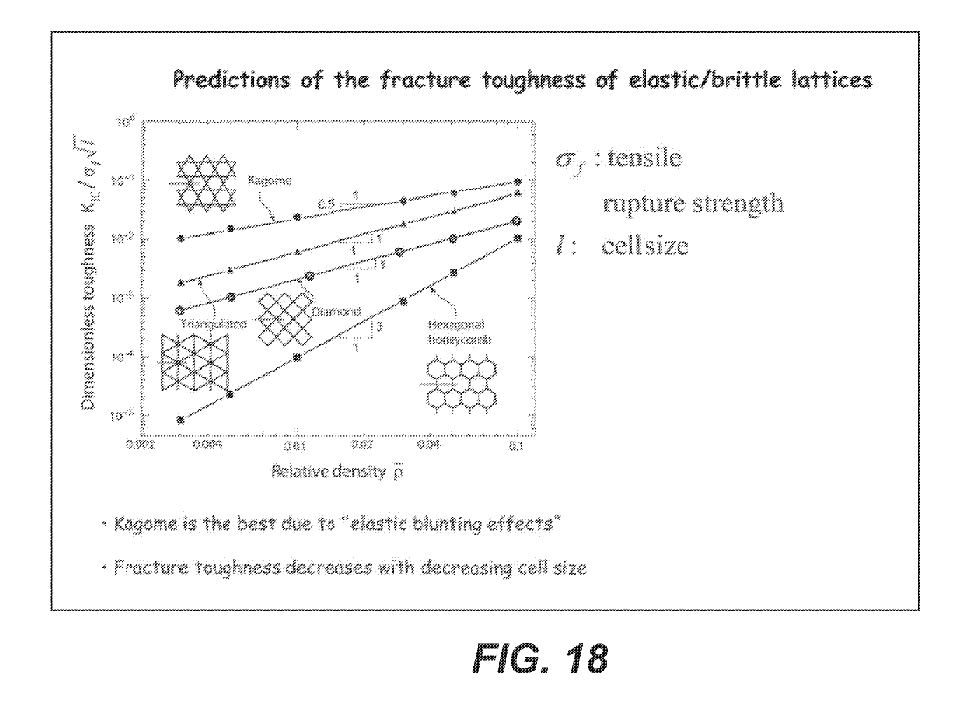

Predictions of the fracture toughness of elastic/brittle lattices is shown in FIG. 18. A graph of dimensionless toughness verses relative density is shown.

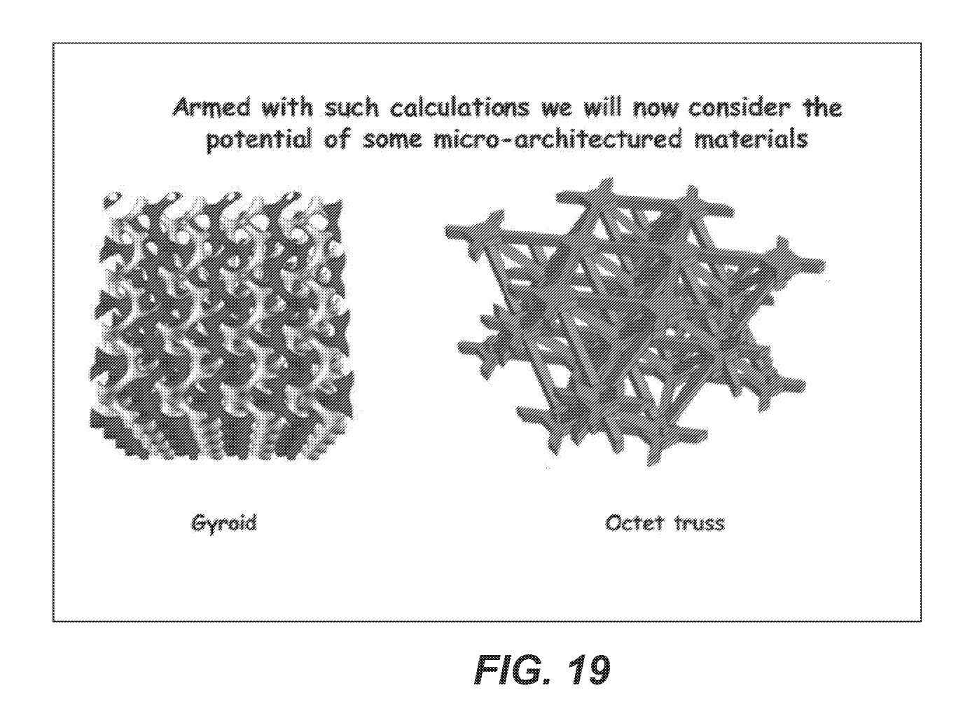

The structure of micro-architectured materials such as gyroid and octet truss are shown in FIG. 19.

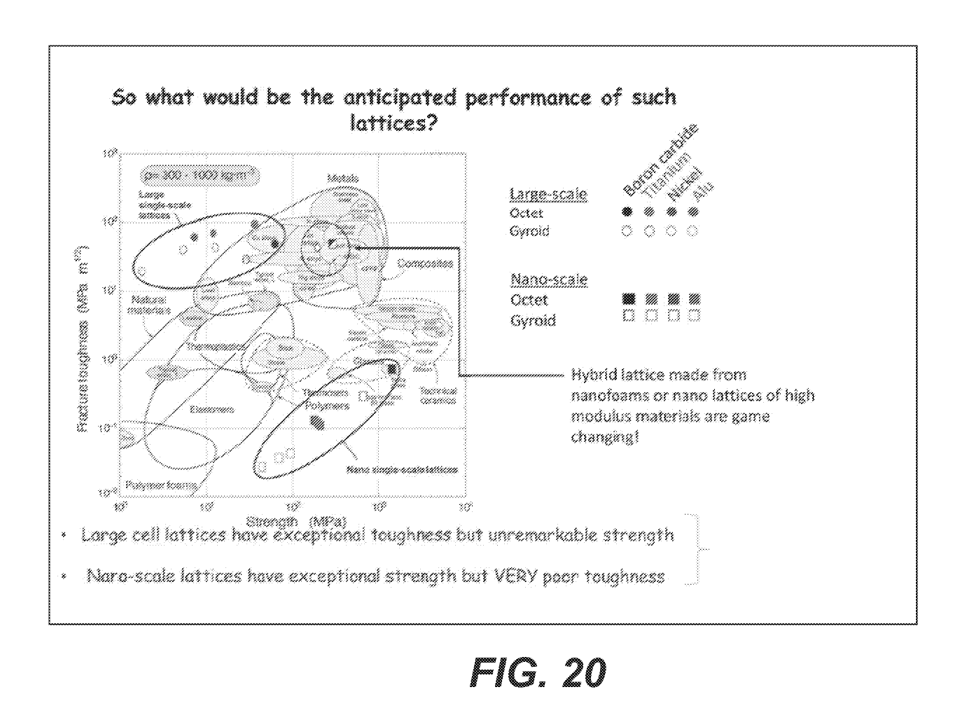

A graph of the fracture toughness verses strength of gyroid and octet truss is shown in FIG. 20. Large cell lattices have exceptional toughness, but unremarkable strength. Nano-scale lattices have exceptional strength, but very poor toughness.

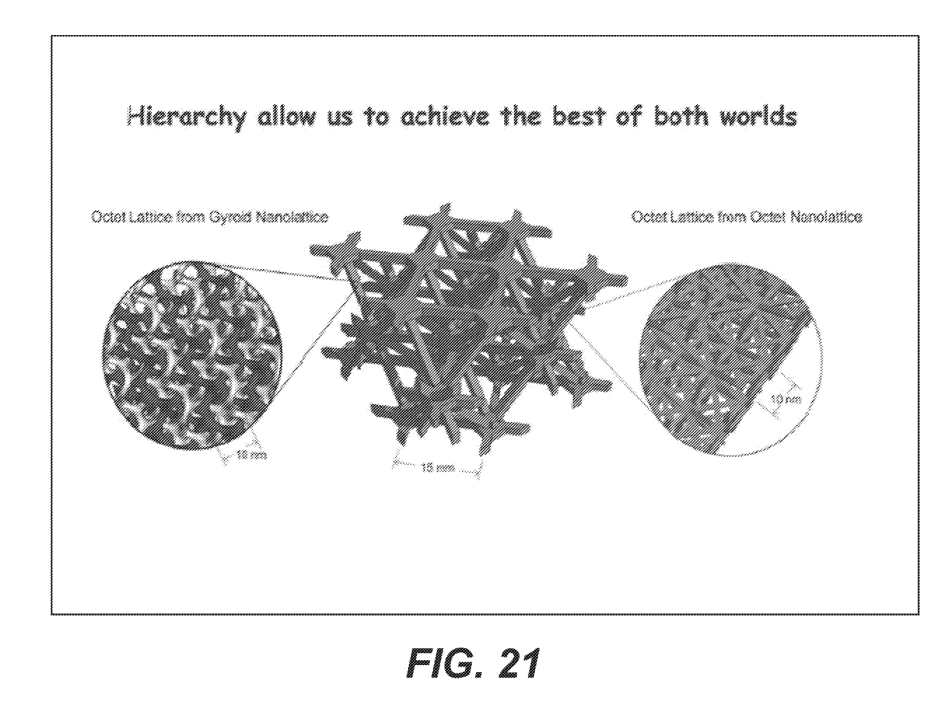

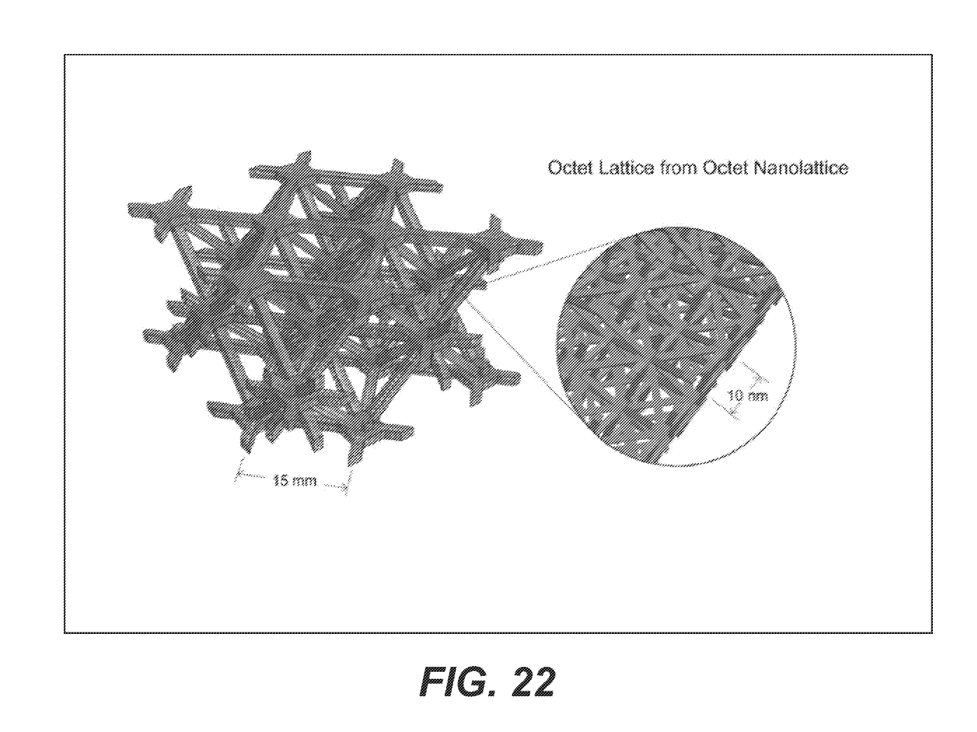

The structure of hierarchical materials, including octet lattice from gyroid nanolattice and octet lattice from octet nanolattice are shown in FIG. 21. The detailed structure of octet lattice from octet nanolattice is shown in FIG. 22.

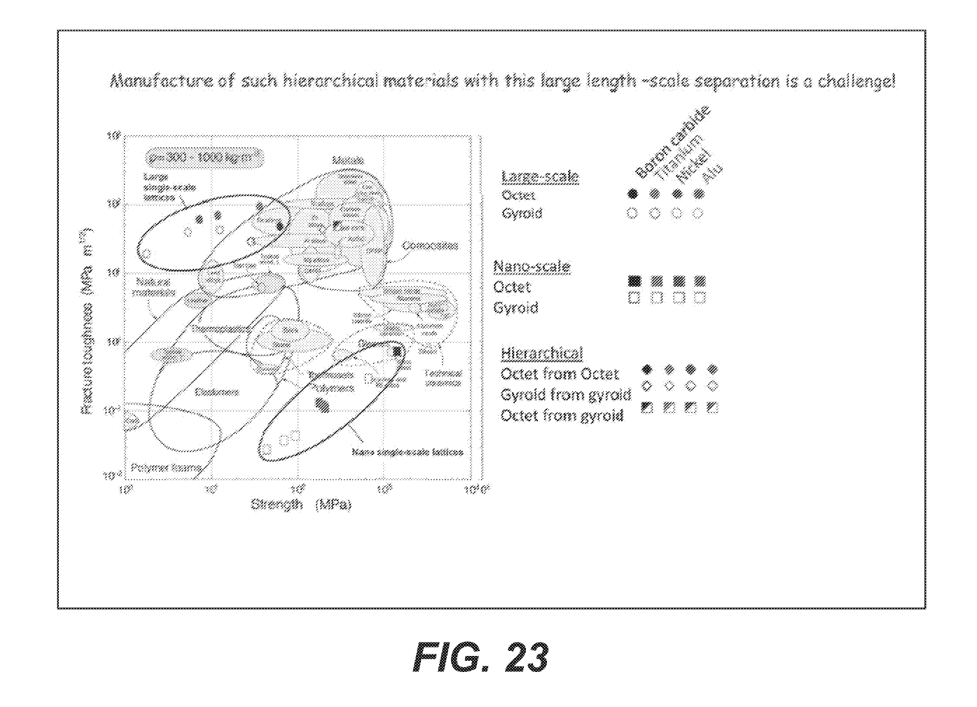

The manufacture of hierarchical materials with this large length-scale separation is a challenge. These material are shown in the graph of fracture toughness verses strength as shown in FIG. 23.

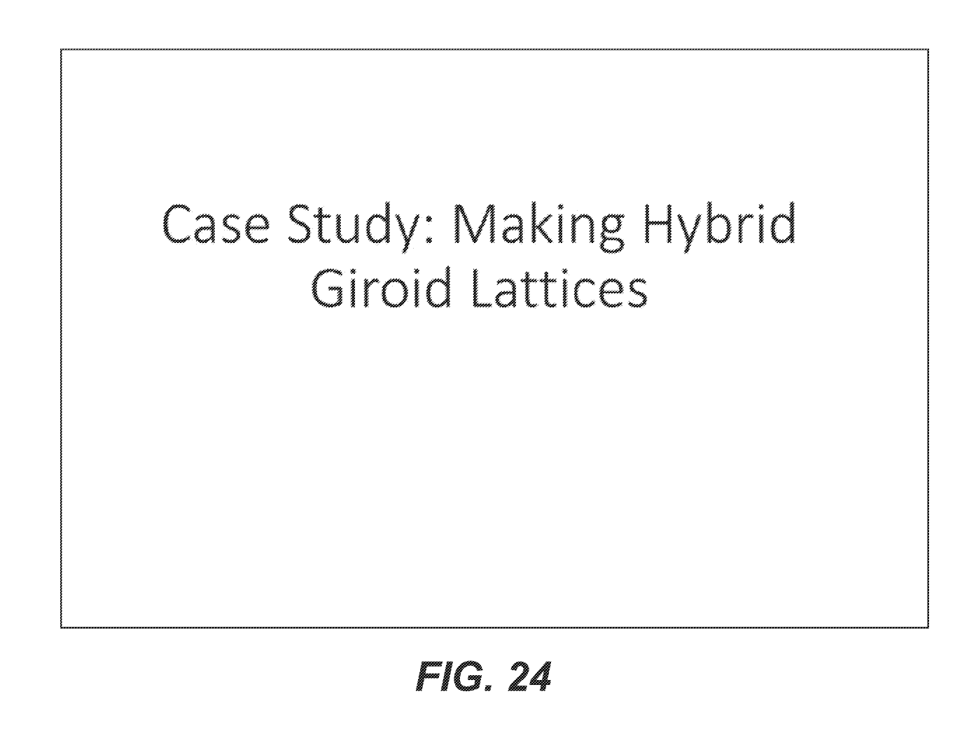

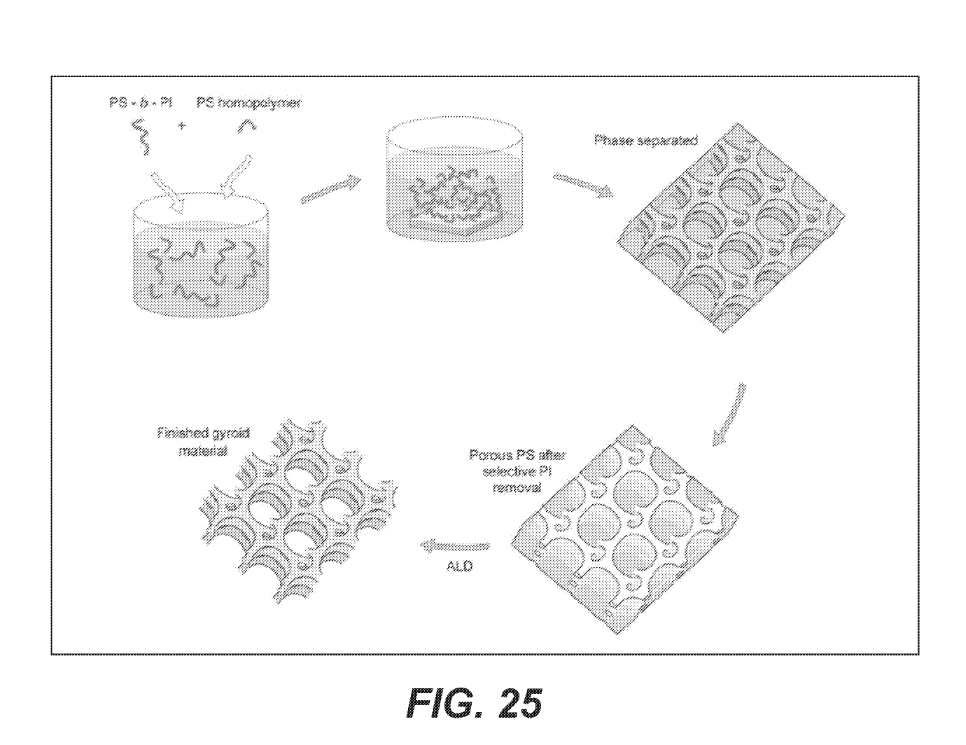

The making of hybrid gyroid lattice begins at FIGS. 24 and 25. A PS-b-PI is mixed with PS homopolymer (FIG. 25); phase separated; porous PS after selective PI removal; and finished gyroid material.

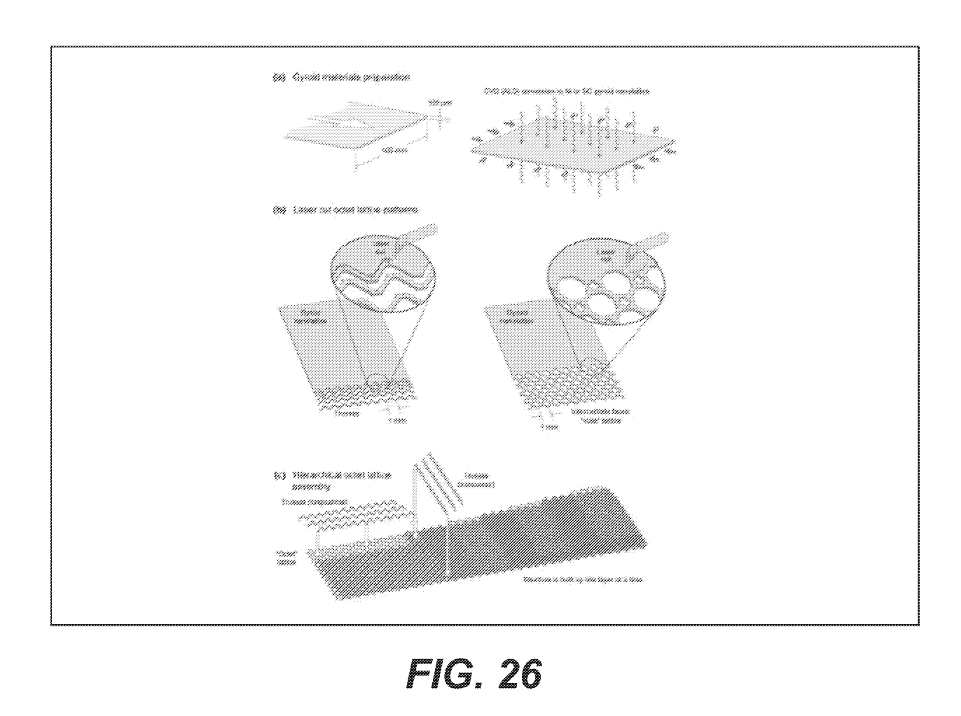

The making of hierarchical octet lattice assembly is shown in FIG. 26. The making includes (a) gyroid materials preparation, including CVD (ALD) conversion to Ni or SiC gyroid lattice; (b) laser cutting octet lattice patterns, including trusses and octet lattice; and (c) hierarchical octet lattice assembly.

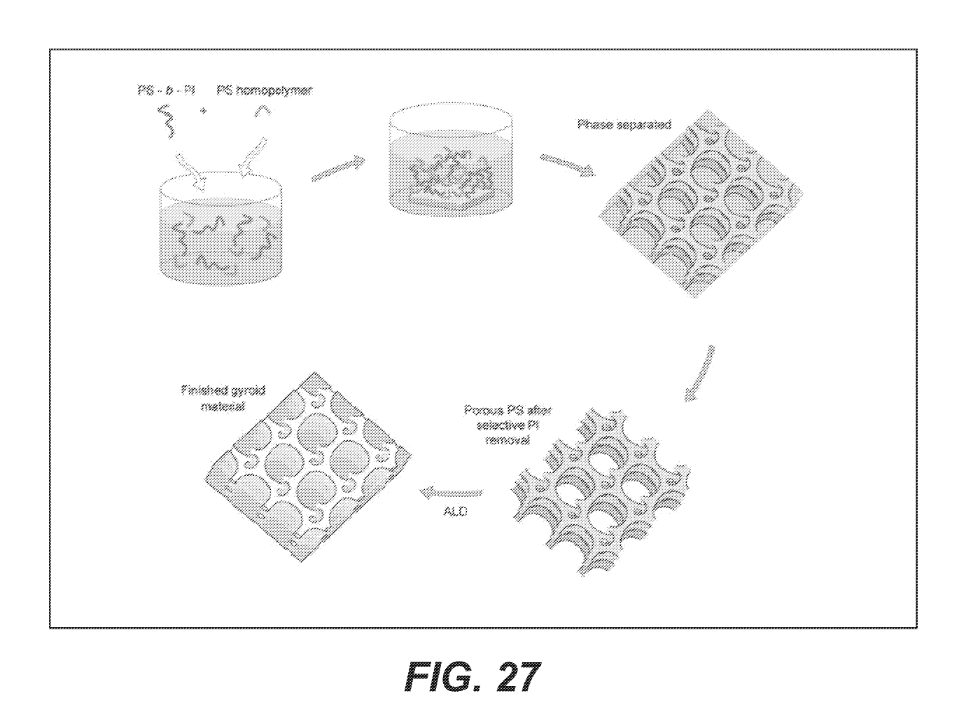

The making of gyroid material is shown in FIG. 27. The making includes mixing together PS-b-PI and PS homopolymer; phase separated; porous PS after selective PI removal; and finished gyroid material.

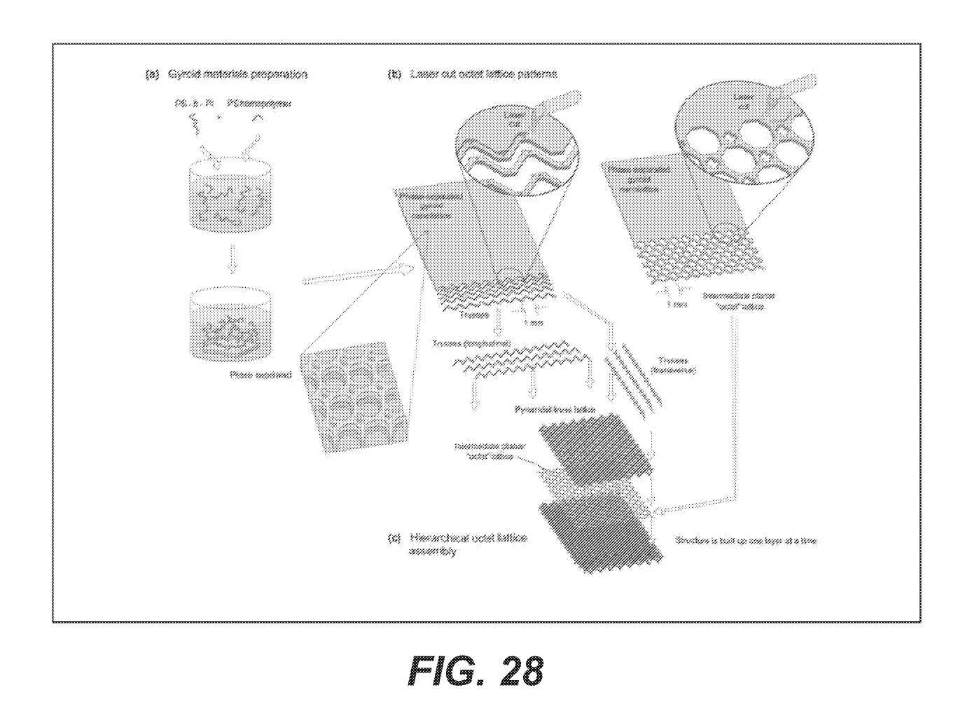

The making of a hierarchical octet lattice assembly is shown in FIG. 28. The making includes (a) gyroid materials preparation (i.e. mixing together PS-b-PI and PS homopolymer); (b) laser cutting octet lattice patterns; and (c) hierarchical octet lattice assembly.

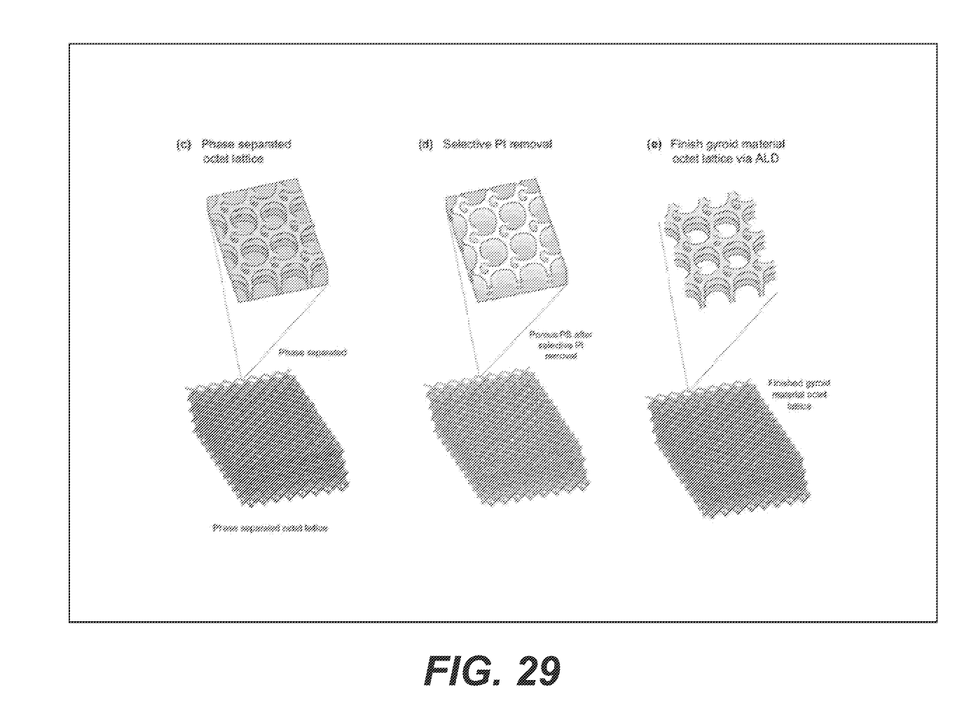

The making of finished gyroid material octet lattice via ALD is shown in FIG. 29. The making includes (a) phase separated octet lattice; (b) selective PI removal; and (c) finish gyroid material octet lattice via ALD.

### Technical Support

The following patents, applications, and/or publications as listed below and throughout this document provide technical support for the invention, and are hereby incorporated by reference in their entirety herein.

It should be appreciated that various aspects of embodiments of the present method, system, devices, article of manufacture, and compositions may be implemented with the following methods, systems, devices, article of manufacture, and compositions disclosed in the following U.S. Patent Applications, U.S. Patents, Publications, and PCT International Patent Applications and are hereby incorporated by reference herein and co-owned with the assignee (and which are not admitted to be prior art with respect to the present invention by inclusion in this section):

International Patent Application Serial No. PCT/US2011/035581, entitled “Spotless Arc Directed Vapor Deposition (SA-DVD) and Related Method Thereof”, filed on May 6, 2011.

International Patent Application Serial No. PCT/US2011/031592, entitled “Multifunctional Armor Panel”, filed on Apr. 7, 2011, and corresponding U.S. application Ser. No. 13/640,239, filed on Oct. 9, 2012; U.S. Patent Application Publication No. US 2013/0263727, published Oct. 10, 2013.

International Patent Application Serial No. PCT/US2011/021121, entitled “Multifunctional Thermal Management System and Related Method”, filed Jan. 13, 2011, and corresponding U.S. patent application Ser. No. 13/522,264, entitled “Multifunctional Thermal Management System and Related Method”, filed Jul. 13, 2012; U.S. Patent Application Publication No. US 2013/0014916, published Jan. 17, 2013.

International Patent Application No. PCT/US2010/025259, entitled “Coaxial Hollow Cathode Plasma Assisted Directed Vapor Deposition and Related Method Thereof”, filed Feb. 24, 2010, and corresponding U.S. patent application Ser. No. 13/202,828, entitled “Coaxial Hollow Cathode Plasma Assisted Directed Vapor Deposition and Related Method Thereof”, filed Aug. 23, 2011; U.S. Patent Application Publication No. US 2011/0318498, published Dec. 29, 2011.

U.S. patent application Ser. No. 12/604,654, entitled “Interwoven Sandwich Panel Structures and Related Methods Thereof”, filed Oct. 23, 2009; U.S. Patent Application Publication No. US 2010/0104819, published Apr. 29, 2010. International Patent Application No. PCT/US2009/061888 entitled “Reactive Topologically Controlled Armors for Protection and Related Method”, filed Oct. 23, 2009.

U.S. patent application Ser. No. 12/479,408, entitled “Manufacture of Lattice Truss Structures from Monolithic Materials”, filed Jun. 5, 2009; U.S. Patent Application Publication Serial No. US 2009/028610, published Nov. 19, 2009.

U.S. patent application Ser. No. 12/408,250, entitled “Cellular Lattice Structures with Multiplicity of Cell Sizes and Related Method of Use”, filed Mar. 20, 2009.

International Application No. PCT/US2009/034690, entitled “Method for Manufacture of Cellular Structure and Resulting Cellular Structure”, filed Feb. 20, 2009.

International Application No. PCT/US2008/073377, entitled “Synergistically-Layered Armor Systems and Methods for Producing Layers Thereof”, filed Aug. 15, 2008, and corresponding U.S. patent application Ser. No. 12/673,647, entitled “Synergistically-Layered Armor Systems and Methods for Producing Layers Thereof”, filed Feb. 16, 2010.

International Patent Application No. PCT/US2008/073071, entitled “Thin Film Battery Synthesis by Directed Vapor Deposition”, filed Aug. 13, 2008, and corresponding U.S. patent application Ser. No. 12/733,160, entitled “Thin Film Battery Synthesis by Directed Vapor Deposition”, filed Feb. 16, 2010.

International Patent Application No. PCT/US2008/071848, entitled “Hybrid Periodic Cellular Material Structures, Systems, and Methods for Blast and Ballistic Protection,” filed Jul. 31, 2008, and corresponding U.S. patent application Ser. No. 12/673,418, entitled “Hybrid Periodic Cellular Material Structures, Systems, and Methods for Blast and Ballistic Protection,” filed Feb. 12, 2010; U.S. Patent Application Publication No. US 2011/0283873, published Nov. 24, 2011.

International Application No. PCT/US2008/060637, entitled “Heat-Managing Composite Structures,” filed Apr. 17, 2008, and corresponding U.S. patent application Ser. No. 12/596,548, entitled “Heat-Managing Composite Structures”, filed Oct. 19, 2009; U.S. Patent Application Publication No. US 2010/0236759, published Sep. 23, 2010.

International Application No. PCT/US2007/022733, entitled “Manufacture of Lattice Truss Structures from Monolithic Materials,” filed Oct. 26, 2007, and corresponding U.S. patent application Ser. No. 12/447,166, entitled “Manufacture of Lattice Truss Structures from Monolithic Materials,” filed Apr. 24, 2009; U.S. Pat. No. 8,176,635, issued May 15, 2012, and corresponding U.S. patent application Ser. No. 13/448,074, entitled “Manufacture of Lattice Truss Structures from Monolithic Materials,” filed Apr. 16, 2012.

International Application No. PCT/US2007/012268, entitled “Method and Apparatus for Jet Blast Deflection,” filed May 23, 2007, and corresponding U.S. patent application Ser. No. 12/301,916, entitled “Method and Apparatus for Jet Blast Deflection,” filed Oct. 7, 2009; U.S. Pat. No. 8,360,361, issued Jan. 29, 2013.

International Patent Application No. PCT/US2006/025978, entitled “Reliant Thermal Barrier Coating System and Related Methods and Apparatus of Making the Same,” filed Jun. 30, 2006, and corresponding U.S. patent application Ser. No. 11/917,585, entitled “Reliant Thermal Barrier Coating System and Related Methods and Apparatus of Making the Same,” filed Dec. 14, 2007; U.S. Pat. No. 8,084,086 issued Dec. 27, 2011, and corresponding U.S. patent application Ser. No. 13/337,133, entitled “Reliant Thermal Barrier Coating System and Related Methods and Apparatus of Making the Same,” filed Dec. 25, 2011; U.S. Patent Application Publication No. 2012/0160166, published Jun. 28, 2012.

International Patent Application No. PCT/US2005/000606, entitled “Apparatus and Method for Applying Coatings onto the Interior Surfaces of Components and Related Structures Produced There from,” filed Jan. 10, 2005, and corresponding U.S. patent application Ser. No. 10/584,682, entitled “Apparatus and Method for Applying Coatings onto the Interior Surfaces of Components and Related Structures Produced There from,” filed Jun. 28, 2006; U.S. Pat. No. 8,110,143, issued Feb. 7, 2012.

International Patent Application No. PCT/US2004/024232, entitled “Method for Application of a Thermal Barrier Coating and Resultant Structure Thereof,” filed Jul. 28, 2004, and corresponding U.S. patent application Ser. No. 10/566,316, entitled “Method for Application of a Thermal Barrier Coating and Resultant Structure Thereof,” filed Jan. 27, 2006.

International Application No. PCT/US04/04608, entitled “Methods for Manufacture of Multilayered Multifunctional Truss Structures and Related Structures There from,” filed Feb. 17, 2004, and corresponding U.S. patent application Ser. No. 10/545,042, entitled “Methods for Manufacture of Multilayered Multifunctional Truss Structures and Related Structures There from,” filed Aug. 11, 2005.

International Patent Application No. PCT/US2003/037485, entitled “Bond Coat for a Thermal Barrier Coating System and Related Method Thereof,” filed Nov. 21, 2003, corresponding to U.S. patent application Ser. No. 10/535,364, entitled “Bond Coat for a Thermal Barrier Coating System and Related Method Thereof,” filed May 18, 2005.

International Patent Application No. PCT/US2003/036035, entitled “Extremely Strain Tolerant Thermal Protection Coating and Related Method and Apparatus Thereof,” filed Nov. 12, 2003, and corresponding to U.S. patent application Ser. No. 10/533,993, entitled “Extremely Strain Tolerant Thermal Protection Coating and Related Method and Apparatus Thereof,” filed May 5, 2005.

International Application No. PCT/US03/27606, entitled “Method for Manufacture of Truss Core Sandwich Structures and Related Structures Thereof,” filed Sep. 3, 2003, and corresponding U.S. patent application Ser. No. 10/526,296, entitled “Method for Manufacture of Truss Core Sandwich Structures and Related Structures Thereof,” filed Mar. 1, 2005; U.S. Pat. No. 7,424,967, issued Sep. 16, 2008.

International Patent Application Serial No. PCT/US03/27605, entitled “Blast and Ballistic Protection Systems and Methods of Making Same,” filed Sep. 3, 2003, and corresponding U.S. patent application Ser. No. 10/526,414, entitled “Blast and Ballistic Protection Systems and Methods of Making Same,” filed Mar. 2, 2005; U.S. Pat. No. 7,913,611, issued Mar. 29, 2011.

International Patent Application No. PCT/US2003/023111, entitled “Method and Apparatus for Dispersion Strengthened Bond Coats for Thermal Barrier Coatings,” filed Jul. 24, 2003, and corresponding U.S. patent application Ser. No. 10/522,076, entitled “Method and Apparatus for Dispersion Strengthened Bond Coats for Thermal Barrier Coatings,” filed Jan. 21, 2005.

International Patent Application Serial No. PCT/US03/23043, entitled “Method for Manufacture of Cellular Materials and Structures for Blast and Impact Mitigation and Resulting Structure,” filed Jul. 23, 2003, and corresponding U.S. patent application Ser. No. 10/522,067, entitled “Method for Manufacture of Cellular Materials and Structures for Blast and Impact Mitigation and Resulting Structure,” filed Jan. 21, 2005.

International Patent Application No. PCT/US2003/017049, entitled “Active Energy Absorbing Cellular Metals and Method of Manufacturing and Using the Same,” filed May 30, 2003, and corresponding U.S. patent application Ser. No. 10/516,052 entitled “Active Energy Absorbing Cellular Metals and Method of Manufacturing and Using the Same,” filed Nov. 29, 2004; U.S. Pat. No. 7,288,326, issued Oct. 30, 2007, and corresponding U.S. patent application Ser. No. 11/857,856, entitled “Active Energy Absorbing Cellular Metals and Method of Manufacturing and Using the Same,” filed Sep. 19, 2007.

International Application No. PCT/US03/16844, entitled “Method for Manufacture of Periodic Cellular Structure and Resulting Periodic Cellular Structure,” filed May 29, 2003, and corresponding U.S. patent application Ser. No. 10/515,572, entitled “Method for Manufacture of Periodic Cellular Structure and Resulting Periodic Cellular Structure,” filed Nov. 23, 2004.

International Patent Application No. PCT/US2003/012920, entitled “Apparatus and Method for Uniform Line of Sight and Non-Line of Sight Coating at High Rate,” filed Apr. 25, 2003, and corresponding U.S. patent application Ser. No. 10/512,161, entitled “Apparatus and Method for Uniform Line of Sight and Non-Line of Sight Coating at High Rate,” filed Oct. 15, 2004; U.S. Pat. No. 7,718,222, issued May 18, 2010.

U.S. patent application Ser. No. 10/246,018, entitled “Apparatus and Method for Intra-layer Modulation of the Material Deposition and Assist Beam and the Multilayer Structure Produced There from,” filed Sep. 18, 2002, and corresponding U.S. patent application Ser. No. 09/634,457, entitled “Apparatus and Method for Intra-Layer Modulation of the Material Deposition and Assist Beam and the Multilayer Structure Produced There from,” filed Aug. 7, 2000; U.S. Pat. No. 6,478,931, issued Nov. 12, 2002.

International Patent Application No. PCT/US2002/28654, entitled “Method and Apparatus for Application of Metallic Alloy Coatings,” filed Sep. 10, 2002, and corresponding to U.S. patent application Ser. No. 10/489,090, entitled “Method and Apparatus Application of Metallic Alloy Coatings,” filed Mar. 9, 2004; U.S. Pat. No. 8,124,178, issued Feb. 28, 2012, and corresponding U.S. patent application Ser. No. 13/371,044, entitled “Method and Apparatus Application of Metallic Alloy Coatings,” filed Feb. 10, 2012; U.S. Patent Application Publication No. US 2012/0137974, published Jun. 7, 2012.

International Patent Application No. PCT/US2002/27116, entitled “Reversible Shape Memory Multifunctional Structural Designs and Method of Using and Making the Same,” filed Aug. 26, 2002, and corresponding U.S. patent application Ser. No. 10/487,291, entitled “Reversible Shape Memory Multifunctional Structural Designs and Method of Using and Making the Same,” filed Feb. 20, 2004; U.S. Pat. No. 7,669,799, issued Mar. 2, 2010. International Application No. PCT/US02/17942, entitled “Multifunctional Periodic Cellular Solids and the Method of Making Thereof,” filed Jun. 6, 2002, and corresponding U.S. patent application Ser. No. 10/479,833, entitled “Multifunctional Periodic Cellular Solids and the Method of Making Thereof,” filed Dec. 5, 2003; U.S. Pat. No. 7,963,085, issued Jun. 21, 2011, and corresponding U.S. patent application Ser. No. 13/164,189, entitled “Multifunctional Periodic Cellular Solids and the Method of Making the Same,” filed Jun. 20, 2011.

International Patent Application No. PCT/US2002/13639, entitled “Method and Apparatus for Efficient Application of Substrate Coating,” filed Apr. 30, 2002, and corresponding U.S. patent application Ser. No. 10/476,309, entitled “Method and Apparatus for Efficient Application of Substrate Coating,” filed Oct. 29, 2003; U.S. Pat. No. 7,879,411, issued Feb. 1, 2011.

International Application No. PCT/US01/25158, entitled “Multifunctional Battery and Method of Making the Same,” filed Aug. 10, 2001, and corresponding U.S. patent application Ser. No. 10/110,368, entitled “Multifunctional Battery and Method of Making the Same,” filed Apr. 9, 2002; U.S. Pat. No. 7,211,348, issued May 1, 2007, and corresponding U.S. patent application Ser. No. 11/788,958, entitled “Multifunctional Battery and Method of Making the Same,” filed Apr. 23, 2007; U.S. Patent Application Publication No. 2007/0269716, published Nov. 22, 2007.

International Application No. PCT/US01/22266, entitled “Method and Apparatus For Heat Exchange Using Hollow Foams and Interconnected Networks and Method of Making the Same,” filed Jul. 16, 2001, and corresponding U.S. patent application Ser. No. 10/333,004, entitled “Heat Exchange Foam,” filed Jan. 14, 2003; U.S. Pat. No. 7,401,643 issued Jul. 22, 2008, and corresponding U.S. patent application Ser. No. 11/928,161, “Method and Apparatus For Heat Exchange Using Hollow Foams and Interconnected Networks and Method of Making the Same,” filed Oct. 30, 2007.

International Application No. PCT/US01/17363, entitled “Multifunctional Periodic Cellular Solids and the Method of Making Thereof,” filed May 29, 2001, and corresponding U.S. patent application Ser. No. 10/296,728, entitled “Multifunctional Periodic Cellular Solids and the Method of Making Thereof,” filed Nov. 25, 2002; U.S. Pat. No. 8,247,333, issued Aug. 21, 2012.

International Patent Application No. PCT/US2001/16693, entitled “A Process and Apparatus for Plasma Activated Deposition in Vacuum,” filed May 23, 2001, and corresponding U.S. patent application Ser. No. 10/297,347, entitled “Process and Apparatus for Plasma Activated Deposition in a Vacuum,” filed Nov. 21, 2002; U.S. Pat. No. 7,014,889, issued Mar. 21, 2006.

International Patent Application No. PCT/US1999/13450, entitled “Apparatus and Method for Producing Thermal Barrier Coatings,” filed Jun. 15, 1999.

International Patent Application No. PCT/US1997/11185, entitled “Production Of Nanometer Particles By Directed Vapor Deposition of Electron Beam Evaporant,” filed Jul. 8, 1997.

U.S. patent application Ser. No. 08/679,435, entitled “Production of Nanometer Particles by Directed Vapor Deposition of Electron Beam Evaporant,” filed Jul. 8, 1996; U.S. Pat. No. 5,736,073, issued Apr. 7, 1998.

U.S. patent application Ser. No. 08/298,614, entitled “Directed Vapor Deposition of Electron Beam Evaporant,” filed Aug. 31, 1994; U.S. Pat. No. 5,534,314, issued Jul. 9, 1996.

The following publications as listed below and throughout this document are hereby incorporated by reference in their entirety herein:
1. Lakes, Materials with Structural Hierarchy, Nature, 361, 11 Feb. 1993.
2. Soler-Illia et al., Chemical Strategies To Design Textured Materials: from Microporous and Mesoporous Oxides to Nanonetworks and Hierarchical Structures, Chem. Rev. 2002, 102, 4093-4138.
3. Birnkrant et al., Layer-in-Layer Hierarchical Nanostructures Fabricated by Combining Holographic Polymerization and Block Copolymer Self-Assembly, Nano Lett., 2007, 7(10), pp 3128-3133.

In summary, while the present invention has been described with respect to specific embodiments, many modifications, variations, alterations, substitutions, and equivalents will be apparent to those skilled in the art. The present invention is not to be limited in scope by the specific embodiment described herein. Indeed, various modifications of the present invention, in addition to those described herein, will be apparent to those of skill in the art from the foregoing description and accompanying drawings. Accordingly, the invention is to be considered as limited only by the spirit and scope of the following disclosure, including all modifications and equivalents.

Still other embodiments will become readily apparent to those skilled in this art from reading the above-recited detailed description and drawings of certain exemplary embodiments. It should be understood that numerous variations, modifications, and additional embodiments are possible, and accordingly, all such variations, modifications, and embodiments are to be regarded as being within the spirit and scope of this application. For example, regardless of the content of any portion (e.g., title, field, background, summary, abstract, drawing figure, etc.) of this application, unless clearly specified to the contrary, there is no requirement for the inclusion in any claim herein or of any application claiming priority hereto of any particular described or illustrated activity or element, any particular sequence of such activities, or any particular interrelationship of such elements. Moreover, any activity can be repeated, any activity can be performed by multiple entities, and/or any element can be duplicated. Further, any activity or element can be excluded, the sequence of activities can vary, and/or the interrelationship of elements can vary. Unless clearly specified to the contrary, there is no requirement for any particular described or illustrated activity or element, any particular sequence or such activities, any particular size, speed, material, dimension or frequency, or any particularly interrelationship of such elements. Accordingly, the descriptions and drawings are to be regarded as illustrative in nature, and not as restrictive. Moreover, when any number or range is described herein, unless clearly stated otherwise, that number or range is approximate. When any range is described herein, unless clearly stated otherwise, that range includes all values therein and all sub ranges therein. Any information in any material (e.g., a United States/foreign patent, United States/foreign patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such incorporated by reference material is specifically not incorporated by reference herein.

1. A method of making a cellular material comprising:
conducting phase separation of block copolymers resulting in a particular morphology;
selective removal of one polymer from the block copolymers to form a lattice;
conducting metal deposition on the lattice; and
dissolving a remaining polymer to obtain the cellular material.

2. The method according to claim 1, wherein the morphology is a gyroid.

3. The method according to claim 2, wherein the morphology is a double gyroid.

4. The method according to claim 1, wherein the morphology is an octet truss.

5. The method according to claim 1, wherein the metal deposition is by electrodeposition.

6. The method according to claim 1, wherein the block copolymer is block copolymer poly(4-fluorostyrene-r-styrene)-b-poly(d,l-lactide) (PFS-b-PLA).

7. The method according to claim 3, wherein the metal gyroid has a strut diameter of 13 nm.

6. The method according to claim 3, wherein the gyroid is a metal gyroid having a unit-cell size of 45 nm.

7. The method according to claim 3, wherein the gyroid is a metal gyroid having a grain size of 500 nm to 1 micron.

8. The method according to claim 1, wherein the gyroid is a metal gyroid having a volume fraction of 40%.

9. The method according to claim 1, including generating an octet lattice from a gyroid nanolattice.

10. The method according to claim 1, including generating an octet lattice from an octet nanolattice.

11. The method according to claim 1, further comprising laser cutting the cellular material to make trusses.

12. The method according to claim 1, further comprising laser cutting the cellular material to make octet lattice.

13. The method according to claim 11, further comprising laser cutting the cellular material to make octet lattice.

14. The method according to claim 13, further comprising assembling the trusses and octet lattice to form hierarchical octet lattice.

15. A method of making a nanolattice comprising:
generating a CAD design for the nanolattice;
using two-photon lithography to generate a polymer skeleton;
conducting sputter/ALD deposition on the polymer skeleton;
exposing internal polymer of polymer skeleton; and
plasma etching polymer skeleton to form a hollow nanolattice.
